(19) United States
(12) Patent Application Publication
(10) Pub. No.: US 2026/0247935 A1
(43) Pub. Date: Aug. 20, 2026

(54) METHOD FOR FORMING A SILICON ON INSULATOR SUBSTRATE

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 19/182,689

(22) Filed: Apr. 18, 2025

Related U.S. Application Data
(60) Provisional application No. 63/760,365, filed on Feb. 19, 2025.

(51) Int. Cl. H10P 90/00; H10D 86/00; H10W 10/10

(52) U.S. Cl. CPC H10P 90/1922; H10D 86/201; H10W 10/181

(57) ABSTRACT

A system and method for an efficient method for creating a silicon on insulator (SOI) wafer are disclosed. The method may include coating an unpolished single-crystalline silicon wafer with a spin-on-glass to create a spin-on-glass layer. The method may also include growing an etch stop layer on a second single-crystalline silicon wafer. The method may additionally include growing a silicon layer on the etch stop layer. The method may include bonding the silicon layer to the spin-on-glass layer. The method may also include polishing back the second single-crystalline silicon wafer. The method may further include removing the etch stop layer to create a silicon on insulator (SOI) substrate.

### PRIORITY

This application claims priority to U.S. Provisional Patent Application No. 63/760,365 filed February 19, 2025, the contents of which are hereby incorporated in their entirety.

### TECHNICAL FIELD

The present disclosure relates to creating a silicon on insulator (SOI) wafer, and, in particular, to an efficient method for creating a SOI wafer.

### BACKGROUND

A silicon-on-insulator (SOI) wafer is a type of silicon wafer engineered to have a layer of silicon dioxide (SiO₂) buried beneath a thin layer of single-crystal silicon. The SOI wafer may have a substrate, typically made of bulk single-crystal silicon to provide mechanical support. A buried oxide (BOX) layer may be sandwiched between the substrate and the top silicon layer to act as an insulator. The top silicon layer may be a device layer made of a thin layer of high-quality, single-crystal silicon on top of the buried oxide.

The buried oxide layer may electrically isolate the device layer from the substrate to reduce parasitic capacitance, leading to faster switching speeds and improved performance in integrated circuits. SOI wafers may be used in a variety of applications including high-performance microprocessors, radio frequency (RF) circuits, microelectromechanical systems (MEMS), and radiation-hardened electronics.

An SOI wafer may be manufactured using one of several techniques including bonded and etch back silicon on insulator (BESOI), separation by implantation of oxygen (SIMOX), bonding, and SmartCut SOI wafer formation.

### SUMMARY OF THE INVENTION

Aspects provide systems and methods for an efficient method for creating a silicon on insulator (SOI) wafer. Examples of the present disclosure may include a method. The method may include coating an unpolished single-crystalline silicon wafer with a spin-on-glass to create a spin-on-glass layer. The method may also include growing an etch stop layer on a second single-crystalline silicon wafer. The method may additionally include growing a silicon layer on the etch stop layer. The method may include bonding the silicon layer to the spin-on-glass layer. The method may also include polishing back the second single-crystalline silicon wafer. The method may further include removing the etch stop layer to create a silicon on insulator (SOI) substrate.

In combination with any of the above examples, the method may include using a thermal oxidation layer to bond the silicon layer to the spin-on-glass layer.

In combination with any of the above examples, the method may include creating a lithography pattern on the SOI substrate. The method may also include etching through the silicon layer and the spin-on-glass layer according to the lithography pattern to create a first portion of the SOI substrate and a second portion of the SOI substrate. The first portion may be a silicon-on-insulator (SOI) portion and the second portion of is a single-crystalline portion.

In combination with any of the above examples, the method may include adding a plurality of particles to the spin-on-glass. The plurality of particles may have a thermal conductivity of less than 2,200 Watts per meter-Kelvin (W/m-K) at zero degrees Kelvin.

In combination with any of the above examples, the etch stop layer may be grown using an epitaxial growth process.

In combination with any of the above examples, the silicon layer may be grown using an epitaxial growth process.

In combination with any of the above examples, removing the etch stop layer may include wet etching the etch stop layer.

Alone or in combination with any of the above examples, examples of the present disclosure may include a silicon on insulator (SOI) substrate. The SOI substrate may be created by a process including coating an unpolished single-crystalline silicon wafer with a spin-on-glass to create a spin-on-glass layer. The process may also include growing an etch stop layer on a second single-crystalline silicon wafer. The process may additionally include growing a silicon layer on the etch stop layer. The process may include bonding the silicon layer to the spin-on-glass layer. The process may also include polishing back the second single-crystalline silicon wafer. The process may further include removing the etch stop layer to create a silicon on insulator (SOI) substrate.

In combination with any of the above examples, the process may include using a thermal oxidation layer to bond the silicon layer to the spin-on-glass layer.

In combination with any of the above examples, the process may include creating a lithography pattern on the SOI substrate. In combination with any of the above examples, the process may include etching through the silicon layer and the spin-on-glass layer according to the lithography pattern to create a first portion of the SOI substrate and a second portion of the SOI substrate. The first portion may be a silicon-on-insulator (SOI) portion and the second portion of is a single-crystalline portion.

In combination with any of the above examples, the process may include adding a plurality of particles to the spin-on-glass. The plurality of particles may have a thermal conductivity of less than 2,200 Watts per meter-Kelvin (W/m-K) at zero degrees Kelvin.

In combination with any of the above examples, the etch stop layer may be grown using an epitaxial growth process.

In combination with any of the above examples, the silicon layer may be grown using an epitaxial growth process.

In combination with any of the above examples, removing the etch stop layer may include wet etching the etch stop layer.

Alone or in combination with any of the above examples, examples of the present disclosure may include a silicon on insulator (SOI) substrate. The SOI substrate may include a first portion. The first portion may include an unpolished single-crystalline silicon wafer. The first portion may also include a spin-on-glass layer coating the unpolished single-crystalline silicon wafer. The first portion may further include a silicon layer bonded to the spin-on-glass layer. The SOI substrate may also include a second portion. The second portion may include a polished single-crystalline silicon wafer.

In combination with any of the above examples, wherein the first portion may include a thermal oxidation layer bonding the silicon layer to the spin-on-glass layer.

In combination with any of the above examples, the spin-on-glass may include a plurality of particles having a thermal conductivity of less than 2,200 Watts per meter-Kelvin (W/m-K) at zero degrees Kelvin.

In combination with any of the above examples, the plurality of particles may be formed of at least one of aluminum nitride, diamond, or silicon carbide.

In combination with any of the above examples, the first portion may include a pad nitride deposition on the silicon layer.

In combination with any of the above examples, the silicon layer may be an epitaxial silicon layer.

### BRIEF DESCRIPTION OF THE DRAWINGS

The figures illustrate examples of systems and methods for an efficient method for creating a silicon on insulator (SOI) wafer.

FIG. 1 illustrates a cross-sectional view of a silicon on insulator wafer during a manufacturing process, according to examples of the present disclosure;

FIG. 2 illustrates a cross-sectional view of a silicon on insulator wafer at a later part of a manufacturing process, according to examples of the present disclosure;

FIG. 3 illustrates a cross-sectional view of an embedded SOI wafer, according to examples of the present disclosure;

FIG. 4 illustrates an example wafer with devices coupled to a single crystal silicon region an SOI region, according to examples of the present disclosure;

FIG. 5 illustrates a vertical insulated-gate bipolar transistor (IGBT) built on a single crystal silicon region, according to examples of the present disclosure;

FIG. 6 illustrates a method for an efficient method for creating a silicon on insulator (SOI) wafer, according to examples of the present disclosure; and

FIG. 7 illustrates a more detailed method for an efficient method for creating a silicon on insulator (SOI) wafer, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a system and method for an efficient method for creating a silicon on insulator (SOI) wafer are provided. Creating an SOI wafer using the disclosed system and method may take less time and be less expensive when compared to conventional methods of creating an SOI wafer. Additionally, the SOI wafer may have lower eddy currents and improved heat transfer, resulting in an SOI wafer with improved resistance to the effects of self-heating. Further, the SOI wafer created using the disclosed system and method may have improved performance when compared to SOI wafers created using conventional methods.

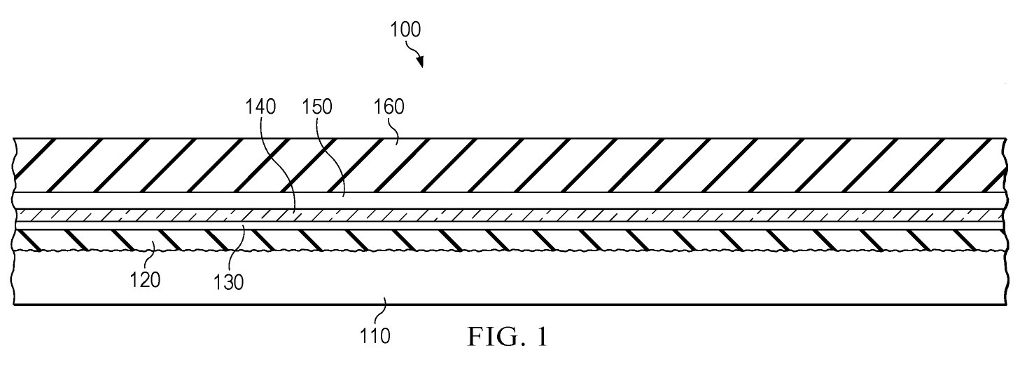

FIG. 1 illustrates a cross-sectional view of a silicon on insulator (SOI) wafer during a manufacturing process, according to examples of the present disclosure. SOI wafer 100 may include single-crystalline wafer 110 as a base. Single-crystalline wafer 110 may be created from an ingot pulled and cut into wafers. The ingot may be pulled faster than a traditional ingot because the process for forming SOI wafer 100 may use ingots having a higher level of defects (e.g., vacancies, self-interstitials, dislocations, pinholes). For example, a traditional ingot may have a defect density lower than 0.5 defects per square centimeter. Single-crystalline wafer 110 may have defects of 1 to 2.5 defects per square centimeter. Single-crystalline wafer 110 may be created faster and for less cost than a conventional single-crystalline wafer because single-crystalline wafer 110 may be a lower grade silicon (e.g., solar-grade Si (1 0 0)) and may be available at a lower cost. Additionally, single-crystalline wafer may not be fully processed after the ingot is cut into wafers. For example, single-crystalline wafer 110 may be lapped, but may not be finely polished. Because single-crystalline wafer 110 is not finely polished, the surface of single-crystalline wafer 110 may not be smooth.

To create a smooth surface to which another layer may be bonded, single-crystalline wafer 110 may be coated with spin-on-glass (SOG) layer 120. The thickness of SOG layer 120 may be between approximately 0.5 to 5 micrometers (μm). For example, the thickness of SOG layer 120 may be approximately 0.5 μm, approximately 1.0 μm, approximately 5 μm, or any other suitable thickness. In some examples, SOG layer 120 may include small particles having a high thermal conductivity, such as, but not limited to, diamond, aluminum nitride (AlN), silicon carbide (SiC), boron nitride (BN), graphene, or any combination thereof. The additional of the small particles may alleviate self-heating effects. SOG layer 120 may act as a buried oxide (BOX) layer of SOI wafer 100. The concentration and size distribution of the small particles may be varied to achieve a given level of thermal conductivity. For example, the small particles may have a size between approximately five micrometers (μm) to approximately fifty μm. The concentration and size distribution of the small particles may be selected to maintain the electrical insulation properties of SOG layer 120 such that SOG layer 120 continues to act as a BOX layer. Because of the addition of the small particles in SOG layer 120 and the improved heat transfer properties of SOG layer 120, SOG layer 120 may thicker than a traditional BOX layer in a traditional SOI wafer.

Thermal oxidation layer 130 may be bonded to SOG layer 120. Thermal oxidation layer 130 may be optional and may be omitted from SOI wafer 100 unless thermal oxidation layer 130 is used to provide an interface between SOG layer 120 and epi silicon layer 140, described in more detail below, without voids. In some examples, SOG layer 120 and epi silicon layer 140 may be bonded together using any suitable technique, such as, but not limited to, direct wafer bonding or plasma-activated bonding.

Silicon wafer 160 may be a single-crystal silicon wafer. Silicon wafer 160 may be, for example, Si (1 0 0) cut from a 6-inch SOI raw wafer. Etch stop layer 150 may be grown on silicon wafer 160. Etch stop layer 150 may be formed of a silicon germanium (SiGe) epitaxial (epi) layer, a silicon carbon (SiC) layer, a silicon-on-nothing (SON) structure, or any other suitable etch stop material. Epi silicon layer 140 may be grown on etch stop layer 150. Silicon wafer 160, etch stop layer 150, and epi silicon layer 140 may be bonded to thermal oxidation layer 130 to create SOI wafer 100.

While FIG. 1 illustrates SOI wafer 100 as including single-crystalline wafer 110, SOG layer 120, thermal oxidation layer 130, epi silicon layer 140, etch stop layer 150, and silicon wafer 160, SOI wafer 100 may include additional layers. For example, a layer of high-k dielectric material may be deposited on top of the epi silicon layer 140 to enhance gate control in subsequent device fabrication. Alternatively, a layer of strained silicon or SiGe may be incorporated to improve carrier mobility in certain device regions.

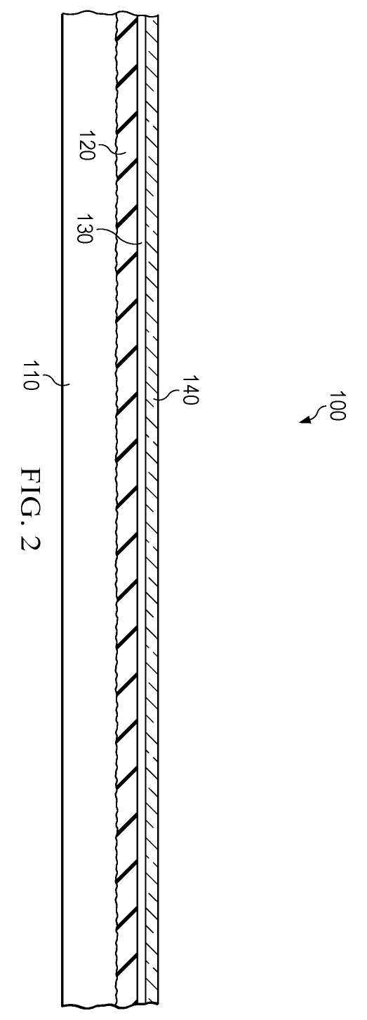

FIG. 2 illustrates a cross-sectional view of a silicon on insulator wafer at a later part of a manufacturing process, according to examples of the present disclosure. SOI wafer 100 as shown in FIG. 2 illustrates SOI wafer 100 from FIG. 1 at a part of the manufacturing process later in time than the part illustrated in FIG. 1.

After the layers of SOI wafer 100 are bonded together, silicon wafer 160, shown in FIG. 1, may be polished back and etch stop layer 150, shown in FIG. 1, may act as an etch stop layer. The use of etch stop layer 150 may be used because optical thickness measurements may not be accurate due to the roughness of single-crystalline wafer 110. However, in some circumstances, instead of etch stop layer 150, other techniques may be used to control the etch of SOI wafer 100, such as, but not limited to, a timing technique or polishing to a predetermined measured thickness.

After silicon wafer 160 is polished back, etch stop layer 150 may be removed using a wet etch process. Therefore, at the end of the manufacturing process, SOI wafer 100 may include single-crystalline wafer 110 as a substrate, SOG layer 120 as a BOX layer, thermal oxidation layer 130, and epi silicon layer 140 as the device layer.

While FIG. 2 illustrates SOI wafer 100 as including single-crystalline wafer 110, SOG layer 120, thermal oxidation layer 130, and epi silicon layer 140, SOI wafer 100 may include additional layers. For example, a layer of high-k dielectric material may be deposited on top of the epi silicon layer 140 to enhance gate control in subsequent device fabrication. Alternatively, a layer of strained silicon or SiGe may be incorporated to improve carrier mobility in certain device regions.

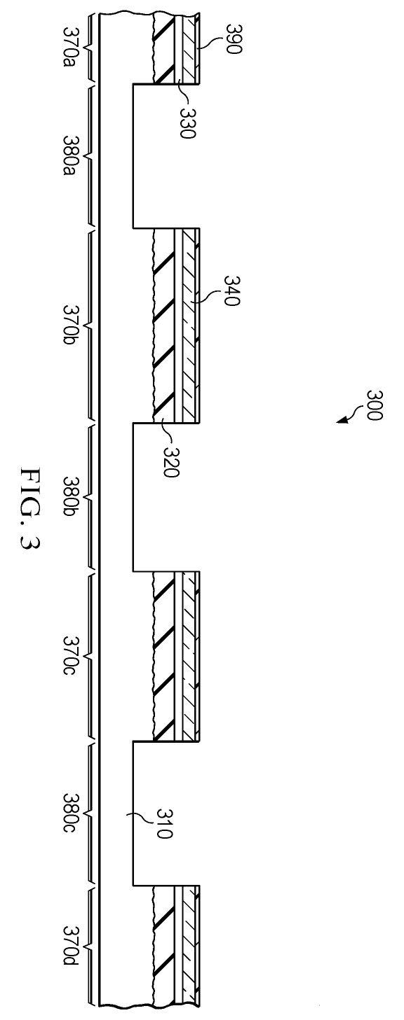

In some examples, an SOI wafer, such as SOI wafer 100 shown in FIG. 2, may be patterned to form an embedded SOI wafer. FIG. 3 illustrates a cross-sectional view of an embedded SOI wafer, according to examples of the present disclosure. Wafer 300 may include SOI regions 370a, 370b, 370c, and 370d and single crystal silicon regions 380a, 380b, 380c. While wafer 300 is shown in FIG. 3 as having four SOI regions 370 and three single crystal silicon regions 380, wafer 300 may include any number of SOI regions 370 and single crystal silicon regions 380.

SOI regions 370 may include single-crystalline wafer 310 as a substrate, SOG layer 320 as a BOX layer, thermal oxidation layer 330, and epi silicon layer 340 as the device layer. Single-crystalline wafer 310, SOG layer 320, thermal oxidation layer 330, and epi silicon layer 340 may be similar to single-crystalline wafer 110, SOG layer 120, thermal oxidation layer 130, and epi silicon layer 140 shown in FIGS. 1 and 2.

Single crystal silicon regions 380a, 380b, 380c may be created by removing SOG layer 320, thermal oxidation layer 330, and epi silicon layer 340 from single-crystalline wafer 310. Single crystal silicon regions 380a, 380b, 380c may be created by creating a lithography pattern on wafer 400 using any suitable technique, such as, but not limited to, photolithography, electron beam lithography (EBL), extreme ultraviolet lithography (EUVL), nanoimprint lithography (NIL), or focused ion beam (FIB) lithography. In single crystal silicon regions 380a, 380b, 380c, single-crystalline wafer 310 may be polished to create a smooth surface on which devices may be bonded. For example, single-crystalline wafer 310 may be fabricated using any suitable etching process, such as, but not limited to, Si:SiO₂ (1:1) reactive-ion etching (RIE), deep reactive ion etching (DRIE), chemical mechanical polishing (CMP), reactive ion beam etching (RIBE), and atomic layer etching (ALE). Single-crystalline wafer 310 may then be cleaned to remove any photoresist materials. For example, the cleaning process include single-atom catalyst (SAC) oxidation, striping the oxide with a wet chemical, and repeating the process to result in a high quality and atomic flat silicon (100) wafer to selectively grow silicon epi. In some examples, the process may be repeated two or three times. Silicon residue may be removed by any suitable cleaning process, such as, but not limited to, touch-up chemical-mechanical planarization (CMP) or plasma polish dry etch (PPDE) removal.

SOI regions 370a, 370b, 370c, and 370d may include pad nitride deposition layer 390 for future selective silicon epi regrowth. Pad nitride deposition layer 390 may have any suitable thickness. For example, pad nitride deposition layer 390 may be between approximately 50 angstroms to approximately 500 angstroms.

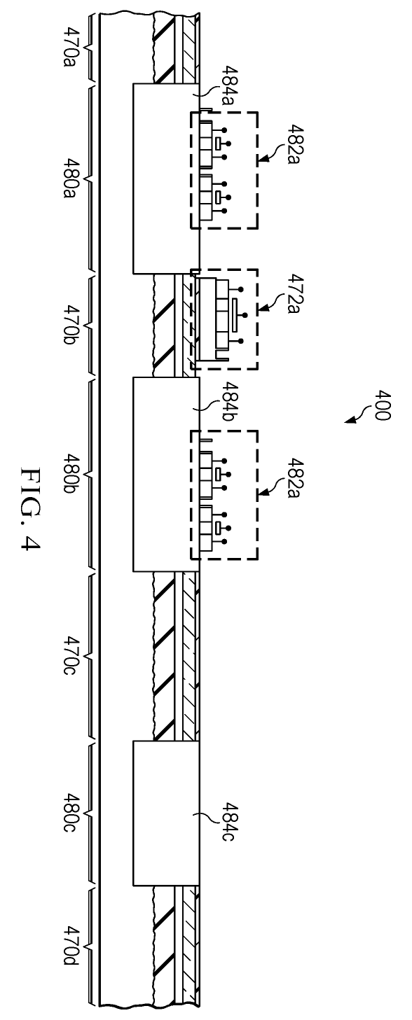

Single crystal silicon regions 380a, 380b, and 380c may be used to allow devices, such as microcontrollers and vertical field-effect transistors (FETs) to be created on single-crystalline wafer 310 in single crystal silicon regions 380a, 380b, and 380c. FIG. 4 illustrates an example wafer with devices coupled to a single crystal silicon region and an SOI region, according to examples of the present disclosure. Wafer 400 may include SOI regions 470a, 470b, 470c, and 470d and single crystal silicon regions 480a, 480b, 480c. SOI regions 470a, 470b, 470c, and 470d may be similar to SOI regions 370a, 370b, 370c, and 370d shown in FIG. 3. Single crystal silicon regions 480a, 480b, 480c may be similar to single crystal silicon regions 380a, 380b, 380c shown in FIG. 3.

Complementary metal-oxide semiconductor (CMOS) 482a may be built on single crystal silicon region 480a and CMOS 482b may be built on single crystal silicon region 480b. In some examples, CMOS 482b and CMOS 482 may be built on single crystal silicon regions 480a and 480b, respectively, via single crystal silicon heat sinks 484a and 484b, respectively.

Laterally diffused metal-oxide-semiconductor (LDMOS) 472a may be built on SOI region 470b. Heat may be transferred from LDMOS 472a through SOI region 470b by the spin-on-glass layer of SOI region 470b and through the silicon of single crystal silicon regions 480a and 480b adjacent to SOI region 470b.

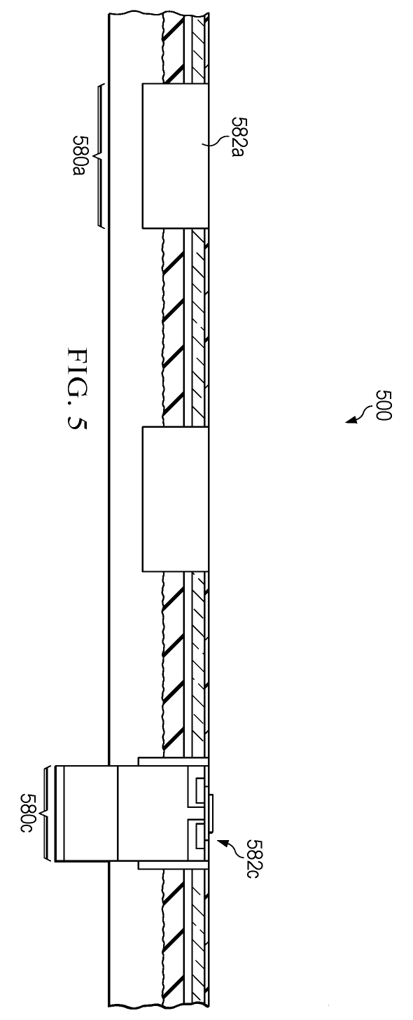

Vertical devices may also be coupled to single crystal silicon regions 380a, 380b, or 380c. For example, FIG. 5 illustrates a vertical insulated-gate bipolar transistor (IGBT) built on a single crystal silicon region, according to examples of the present disclosure. Single crystal silicon regions 580a and 580c may be similar to single crystal silicon regions 380a, 380b, 380c shown in FIG. 3. Wafer 500 may include microcontroller 582a built on single crystal silicon region 580a. Wafer 500 may also include IGBT 582c built on single crystal silicon region 580c.

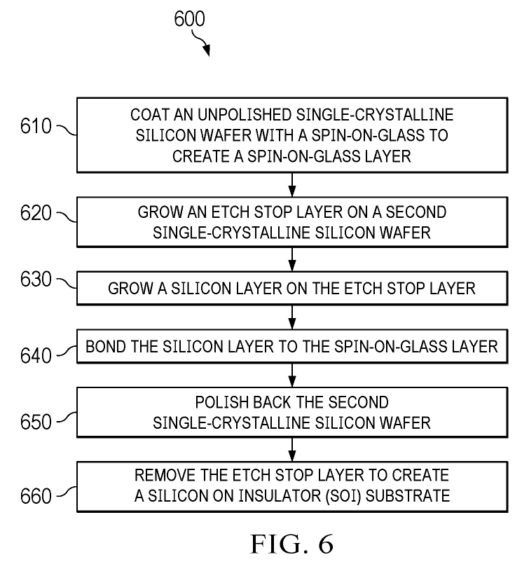

FIG. 6 illustrates a method for an efficient method for creating a silicon on insulator (SOI) wafer, according to examples of the present disclosure. Method 600 may be implemented using any suitable semiconductor manufacturing device designed to perform the functions disclosed herein or any other system operable to implement method 600. Although examples have been described above, other variations and examples may be made from this disclosure without departing from the spirit and scope of these disclosed examples.

Method 600 may begin at block 610 where an unpolished single-crystalline silicon wafer may be coated with a spin-on-glass to create a spin-on-glass layer. The unpolished single-crystalline wafer may be created from an ingot pulled and cut into wafers. The ingot may be pulled faster than a traditional ingot because method 600 may use ingots having a higher level of defects (e.g., vacancies, self-interstitials, dislocations, pinholes). The unpolished single-crystalline wafer may be created faster and for less cost than a conventional single-crystalline wafer because the unpolished single-crystalline wafer may be a lower grade silicon and may be available at a lower cost. Additionally, the unpolished single-crystalline wafer may not be fully processed after the ingot is cut into wafers. For example, the unpolished single-crystalline wafer may be lapped, but may not be finely polished. Because the unpolished single-crystalline wafer is not finely polished, the surface of the unpolished single-crystalline wafer may not be smooth.

The spin-on-glass coating the unpolished single-crystalline wafer may create a smooth surface to which another layer may be bonded to the spin-on-glass layer. The thickness of the spin-on-glass layer may be approximately 0.5 μm, approximately 1.0 μm, approximately 5 μm, or any other suitable thickness.

At block 620, an etch stop layer may be grown on a second single-crystalline silicon wafer. The second single-crystalline silicon wafer may be, for example, Si (1 0 0) cut from a 6-inch SOI raw wafer. The etch stop layer may be formed using an epitaxial grown process and include silicon germanium (SiGe) epitaxial (epi), silicon carbon (SiC), silicon-on-nothing (SON), or any other suitable etch stop material.

At block 630, a silicon layer may be grown on the etch stop layer. The silicon layer may be formed using an epitaxial grown process and include any suitable material, such as epitaxial silicon. In some examples where an etch stop layer is not used, blocks 620 and 630 may be omitted.

At block 640, the silicon layer may be bonded to the spin-on-glass layer. The silicon layer may be bonded to the spin-on-glass layer using any suitable bonding technique, such as, but not limited to, direct wafer bonding or plasma-activated bonding.

At block 650, the second single-crystalline silicon wafer may be polished back to remove the second single-crystalline silicon wafer. The etch stop layer may act as a stop to the polishing.

At block 660, the etch stop layer may be removed to create a silicon on insulator (SOI) substrate. The etch stop layer may be removed using any suitable technique, such as a wet etch process. Once the etch stop layer is removed, the unpolished single-crystalline silicon wafer, spin-on-glass layer, and silicon layer may form a SOI substrate. The silicon layer may form a polished single crystalline silicon wafer.

Although FIG. 6 discloses a particular number of operations related to method 600, method 600 may be executed with greater or fewer operations than those depicted in FIG. 6. In addition, although FIG. 6 discloses a certain order of operations to be taken with respect to method 600, the operations comprising method 600 may be completed in any suitable order.

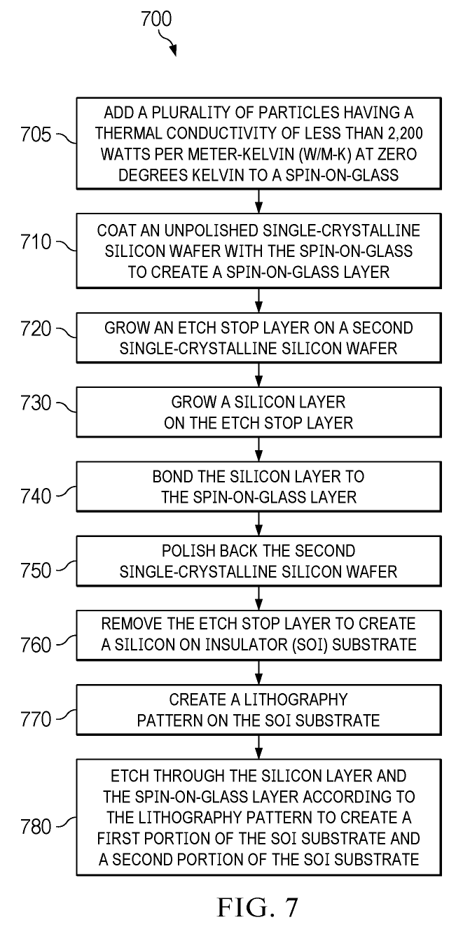

FIG. 7 illustrates a more detailed method for an efficient method for creating a silicon on insulator (SOI) wafer, according to examples of the present disclosure. Method 700 may be implemented using any suitable semiconductor manufacturing device designed to perform the functions disclosed herein or any other system operable to implement method 700. Although examples have been described above, other variations and examples may be made from this disclosure without departing from the spirit and scope of these disclosed examples.

Method 700 may begin at block 705, where a plurality of particles having a thermal conductivity of less than 2,200 Watts per meter-Kelvin (W/m-K) at zero degrees Kelvin to the spin-on-glass. The small particles may be, for example, diamond, aluminum nitride (AlN), silicon carbide (SiC), boron nitride (BN), graphene, or any combination thereof. The small particles may alleviate self-heating effects in the substrate created by method 700.

At block 710, an unpolished single-crystalline silicon wafer may be coated with a spin-on-glass to create a spin-on-glass layer. The unpolished single-crystalline wafer may be created from an ingot pulled and cut into wafers. The ingot may be pulled faster than a traditional ingot because method 600 may use ingots having a higher level of defects (e.g., vacancies, self-interstitials, dislocations, pinholes). The unpolished single-crystalline wafer may be created faster and for less cost than a conventional single-crystalline wafer because the unpolished single-crystalline wafer may be a lower grade silicon and may be available at a lower cost. Additionally, the unpolished single-crystalline wafer may not be fully processed after the ingot is cut into wafers. For example, the unpolished single-crystalline wafer may be lapped, but may not be finely polished. Because the unpolished single-crystalline wafer is not finely polished, the surface of the unpolished single-crystalline wafer may not be smooth.

The spin-on-glass coating the unpolished single-crystalline wafer may create a smooth surface to which another layer may be bonded to the spin-on-glass layer. The thickness of the spin-on-glass layer may be approximately 0.5 μm, approximately 1.0 μm, approximately 5 μm, or any other suitable thickness.

At block 720, an etch stop layer may be grown on a second single-crystalline silicon wafer. The second single-crystalline silicon wafer may be, for example, Si (1 0 0) cut from a 6-inch SOI raw wafer. The etch stop layer may be formed using an epitaxial grown process and include silicon germanium (SiGe) epitaxial (epi), silicon carbon (SiC), silicon-on-nothing (SON), or any other suitable etch stop material.

At block 730, a silicon layer may be grown on the etch stop layer. The silicon layer may be formed using an epitaxial grown process and include any suitable material, such as epitaxial silicon. In some examples where an etch stop layer is not used, blocks 720 and 730 may be omitted.

At block 740, the silicon layer may be bonded to the spin-on-glass layer. The silicon layer may be bonded to the spin-on-glass layer using any suitable bonding technique, such as, but not limited to, direct wafer bonding or plasma-activated bonding.

At block 750, the second single-crystalline silicon wafer may be polished back to remove the second single-crystalline silicon wafer. The etch stop layer may act as a stop to the polishing.

At block 760, the etch stop layer may be removed to create a silicon on insulator (SOI) substrate. The etch stop layer may be removed using any suitable technique, such as a wet etch process. Once the etch stop layer is removed, the unpolished single-crystalline silicon wafer, spin-on-glass layer, and silicon layer may form a SOI substrate. The silicon layer may form a polished single crystalline silicon wafer.

At block 770, a lithography pattern may be created on the SOI substrate. The lithography pattern may be created using any suitable technique, such as, but not limited to, photolithography, electron beam lithography (EBL), extreme ultraviolet lithography (EUVL), nanoimprint lithography (NIL), or focused ion beam (FIB) lithography.

At block 780, the silicon layer and the spin-on-glass layer may be etched according to the lithography pattern (etched at block 770) to create a first portion of the SOI substrate and a second portion of the SOI substrate. The first portion of the SOI substrate may be an SOI portion including the unpolished single-crystalline wafer, the spin-on-glass layer, and the silicon layer. The second portion of the SOI substrate may be a single-crystalline portion. The single-crystalline portion may be polished such that electrical devices may be coupled to the single-crystalline portion.

Although FIG. 7 discloses a particular number of operations related to method 700, method 700 may be executed with greater or fewer operations than those depicted in FIG. 7. In addition, although FIG. 7 discloses a certain order of operations to be taken with respect to method 700, the operations comprising method 700 may be completed in any suitable order.

Although examples have been described above, other variations and examples may be made from this disclosure without departing from the spirit and scope of these disclosed examples.

1. A method, comprising:
coating an unpolished single-crystalline silicon wafer with a spin-on-glass to create a spin-on-glass layer;
growing an etch stop layer on a second single-crystalline silicon wafer;
growing a silicon layer on the etch stop layer;
bonding the silicon layer to the spin-on-glass layer;
polishing back the second single-crystalline silicon wafer; and
removing the etch stop layer to create a silicon on insulator (SOI) substrate.

2. The method of claim 1, comprising using a thermal oxidation layer to bond the silicon layer to the spin-on-glass layer.

3. The method of claim 1, comprising:
creating a lithography pattern on the SOI substrate; and
etching through the silicon layer and the spin-on-glass layer according to the lithography pattern to create a first portion of the SOI substrate and a second portion of the SOI substrate;
wherein the first portion is a silicon-on-insulator (SOI) portion and the second portion of is a single-crystalline portion.

4. The method of claim 1, comprising adding a plurality of particles to the spin-on-glass, the plurality of particles having a thermal conductivity of less than 2,200 Watts per meter-Kelvin (W/m-K) at zero degrees Kelvin.

5. The method of claim 1, wherein the etch stop layer is grown using an epitaxial growth process.

6. The method of claim 1, wherein the silicon layer is grown using an epitaxial growth process.

7. The method of claim 1, wherein removing the etch stop layer includes wet etching the etch stop layer.

8. A silicon on insulator (SOI) substrate, created by a process comprising:
coating an unpolished single-crystalline silicon wafer with a spin-on-glass to create a spin-on-glass layer;
growing an etch stop layer on a second single-crystalline silicon wafer;
growing a silicon layer on the etch stop layer;
bonding the silicon layer to the spin-on-glass layer;
polishing back the second single-crystalline silicon wafer; and
removing the etch stop layer to create a silicon on insulator (SOI) substrate.

9. The SOI substrate of claim 8, the process comprising using a thermal oxidation layer to bond the silicon layer to the spin-on-glass layer.

10. The SOI substrate of claim 8, the process comprising:
creating a lithography pattern on the SOI substrate; and
etching through the silicon layer and the spin-on-glass layer according to the lithography pattern to create a first portion of the SOI substrate and a second portion of the SOI substrate;
wherein the first portion is a silicon-on-insulator (SOI) portion and the second portion of is a single-crystalline portion.

11. The SOI substrate of claim 8, the process comprising adding a plurality of particles to the spin-on-glass, the plurality of particles having a thermal conductivity of less than 2,200 Watts per meter-Kelvin (W/m-K) at zero degrees Kelvin.

12. The SOI substrate of claim 8, wherein the etch stop layer is grown using an epitaxial growth process.

13. The SOI substrate of claim 8, wherein the silicon layer is grown using an epitaxial growth process.

14. The SOI substrate of claim 8, wherein removing the etch stop layer includes wet etching the etch stop layer.

15. A silicon on insulator (SOI) substrate, comprising:
a first portion including:
an unpolished single-crystalline silicon wafer;
a spin-on-glass layer coating the unpolished single-crystalline silicon wafer; and
a silicon layer bonded to the spin-on-glass layer; and
a second portion including a polished single-crystalline silicon wafer.

16. The SOI substrate of claim 15, wherein the first portion includes a thermal oxidation layer bonding the silicon layer to the spin-on-glass layer.

17. The SOI substrate of claim 15, wherein the spin-on-glass includes a plurality of particles having a thermal conductivity of less than 2,200 Watts per meter-Kelvin (W/m-K) at zero degrees Kelvin.

18. The SOI substrate of claim 17, wherein the plurality of particles are formed of at least one of aluminum nitride, diamond, or silicon carbide.

19. The SOI substrate of claim 15, wherein the first portion includes a pad nitride deposition on the silicon layer.

20. The SOI substrate of claim 15, wherein the silicon layer is an epitaxial silicon layer.
